(19) United States
(12) Patent Application Publication
(10) Pub. No.: US 2013/0248623 A1
(43) Pub. Date: Sep. 26, 2013

(54) Piezoelectric Component with Contact

(71) Applicants: Harald Johannes Kastl, Fichtelberg (DE); Christian Reichinger, Neutraubling (DE); Christoph Hamann, Thalmassing (DE)

(72) Inventors: Harald Johannes Kastl, Fichtelberg (DE); Christian Reichinger, Neutraubling (DE); Christoph Hamann, Thalmassing (DE)

(21) Appl. No.: 13/881,156

(22) PCT Filed: Oct. 5, 2011
(86) PCT No.: PCT/EP2011/067361

§ 371 Date: Jun. 11, 2013

(30) Foreign Application Priority Data
Oct. 26, 2010 (DE) 10 2010 042 969.4

(51) Int. Cl. H01L 41/083; F02M 51/06

(52) U.S. Cl. CPC H01L 41/0838; F02M 51/0603
USPC 239/585.1; 310/366

(57) ABSTRACT

A piezoelectric component, e.g., for use as an actuator of a fuel injection valve in a motor vehicle, may include a stack-shaped actuator body including a plurality of piezoelectric elements and inner electrode layers arranged in an alternating manner in a stacking direction, each inner electrode layer being connected alternately to one of two metalizations on an outer face of the stack in an electrically conductive manner. Each metalization is connected to an electrically conductive electrode structure via an electrically conductive contacting element (e.g., adhesive or solder). The stack-shaped actuator body has at least one predetermined breaking point, and the metalizations and/or the contacting elements have a recess in the region of the at least one predetermined breaking point.

### CROSS-REFERENCE TO RELATED APPLICATIONS

This application is a U.S. National Stage Application of International Application No. PCT/EP2011/067361 filed Oct. 5, 2011, which designates the United States of America, and claims priority to DE Application No. 10 2010 042 969.4 filed Oct. 26, 2010, the contents of which are hereby incorporated by reference in their entirety.

### TECHNICAL FIELD

The disclosure relates to a piezoelectric component comprising a stack-like actuator body, in which a plurality of piezoelectric elements and internal electrode layers are arranged in an alternating manner in a stacking direction. In this case, the internal electrode layers are each alternately electrically conductively connected to one of two metallizations on an outer face of the stack. The two metallizations are each connected to an electrically conductive electrode structure by an electrically conductive contact element. The piezoelectric component may be embodied, for example, as a piezoelectric actuator in a fuel injection valves for a motor vehicle.

### BACKGROUND

Piezoelectric components of this kind are used, for example, as piezoelectric actuators in fuel injection valves for motor vehicles. It is known that stack-like actuator bodies of this type, also called piezo stacks in the text which follows, tend to develop cracks. In particular, monolithic piezo stacks, in which the internal electrodes do not each extend over the entire cross-sectional area of the piezo stack, exhibit inactive regions in which the piezoelectric elements which are arranged in between are not deflected when a voltage is applied. In contrast, the piezoelectric element is expanded when a voltage is applied in the active region of the piezo stack, in which each piezoelectric layer is arranged between two electrodes. Therefore, during operation and even during polarization, voltages which lead to cracks in the piezoelectric elements can be produced in the boundary region between this active region and the inactive region.

Cracks of this type can spread over the metallizations on the side faces of the piezo stack during operation. In order to avoid breakdown of the piezo stack, the outer metallizations are reinforced, for example, by metallic structures, such as wire meshes or the like. Said metallic structures are designed, for example, in such a way that they can bridge cracks in the metallization at any desired points and therefore prevent disconnection of individual subregions of the piezo stack from the power supply.

More recent developments in stack production have, on account of the introduction of predetermined breaking points, led to the piezo stacks breaking at defined points. In this case, for example, porous intermediate layers, which preferably break when the stack is mechanically overloaded, are provided during stack production. On account of a crack of this type, the piezo stack can be, for example, completely separated into two stack elements. Piezo stacks with predetermined breaking points are known, for example, from DE 10 2004 031 402 A1 and DE 10 2004 031 404 A1.

Known contact-making arrangements, for example with a wire meshing, which can bridge the cracks in a piezo stack which occur in the outer metallization place high demands on the metallic structures used and are accordingly expensive.

### SUMMARY

One embodiment provides a piezoelectric component, comprising a stack-like actuator body, in which a plurality of piezoelectric elements and internal electrode layers are arranged in an alternating manner in a stacking direction, wherein the internal electrode layers are each alternately electrically conductively connected to one of two metallizations on an outer face of the stack, and the metallizations are each connected to an electrically conductive electrode structure by an electrically conductive contact element, wherein the stack-like actuator body has at least one predetermined breaking point, and the metallizations and/or the contact elements have/has a cutout in the region of the at least one predetermined breaking point.

In a further embodiment, the contact elements, with the exception of the region of the at least one predetermined breaking point, form a fixed connection between the metallizations and the electrode structures.

In a further embodiment, the contact elements comprise solder or conductive adhesive.

In a further embodiment, the electrode structure is designed to be expandable at least in the region of the at least one predetermined breaking point.

In a further embodiment, the electrode structure has a metallic mesh or has a meandering metallic structure at least in parts.

In a further embodiment, the stack-like actuator body is of monolithic design.

Other embodiments provide a fuel injection valve for use in a motor vehicle, the fuel injection comprising a piezoelectric component including any of the features disclosed above.

### BRIEF DESCRIPTION OF THE DRAWINGS

Exemplary embodiments will be explained in more detail below based on the schematic drawings, wherein:

FIG. 1 schematically shows an example piezoelectric component according to a first example embodiment; and

FIG. 2 shows a piezoelectric component according to a second example embodiment.

### DETAILED DESCRIPTION

Embodiments of the present disclosure provide an improved contact-making arrangement for a piezo stack, which contact-making arrangement avoids the abovementioned problems.

Some embodiments provide a piezoelectric component comprising a stack-like actuator body, in which a plurality of piezoelectric elements and internal electrode layers are arranged in an alternating manner in a stacking direction. The internal electrode layers are each alternately electrically conductively connected to one of two metallizations on an outer face of the stack. The metallizations are each connected to an electrically conductive electrode structure by an electrically conductive contact element.

In this case, the stack-like actuator body has at least one predetermined breaking point, and the metallizations and/or the contact elements have/has a cutout in the region of the at least one predetermined breaking point.

Some embodiments provide a fuel injection valve for a motor vehicle, wherein the valve comprises a piezoelectric actuator as disclosed herein.

Some embodiments are based on the fact that the expansion of the piezo stack is distributed largely homogeneously over the length of the piezo stack in the interior of the piezo stack when a voltage is applied. However, in the outer region, that is to say on the outer faces with the main contact-making arrangements, the expansion in length is concentrated in the region of the predetermined breaking points by the predetermined breaking points. A crack in the piezo stack at the predetermined breaking point can lead to separation of the metallization. Therefore, the two subregions, which adjoin the predetermined breaking point, of the outer faces of the stack are subject to a comparatively large relative shift in relation to one another in the event of a change in length of the total stack. In contrast, the relative change in length of the outer face of the stack between two predetermined breaking points is comparatively low.

This permits a fixed connection between the metallization and the electrode structures in the case of the disclosed piezoelectric component, with the exception of the region of the predetermined breaking points. In order to establish a fixed connection of this type, the contact elements may comprise solder or conductive adhesive. Even when there is a largely flat contact-connection between the electrode structures and the metallization outside the region of the predetermined breaking points, this can follow a relatively small change in length. To this end, the entire electrode structure may be expandable or at least flexible.

However, the electrode structure may be designed to be expandable at least in the region of the predetermined breaking points. This provides the advantage that the electrode structure can also bridge a comparatively large relative change in length in the region of the predetermined breaking point. Therefore, a reliable contact-connection can be ensured over the entire stack length. The electrode structure may be designed to be elastically expandable at least in the region of the predetermined breaking point.

An expandable electrode structure of this type can be formed, for example, by a metallic mesh or a meandering metallic structure. In this case, the ability to expand can be realized due to the shaping of the electrode structure in combination with an ability of the material to deform.

The stack-like actuator body of the piezoelectric component may preferably be a monolithically designed piezo stack in which piezoceramic layers and internal electrodes are stacked and sintered to form a block. Making contact with the piezoelectric component may be advantageous for use in piezoelectric stacks which, on account of the design of the internal electrodes, have active and inactive regions. However, in principle, the piezo stack can also be a fully active stack in which the internal electrodes cover the entire cross-sectional area of the stack. There are no inactive regions in fully active piezo stacks of this kind since, when a voltage is applied, voltage is passed through all the piezoceramic layers by virtue of the applied electrodes and therefore said piezoceramic layers are deflected.

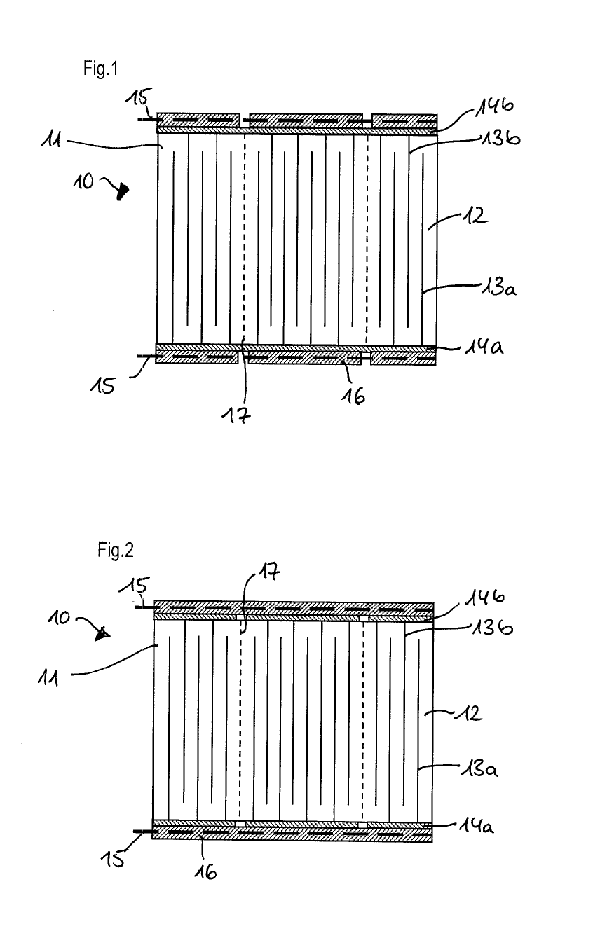

The piezoelectric component 10 illustrated in FIG. 1, which may be embodied for example as a piezoelectric actuator of a fuel injection valve in a motor vehicle, comprises a stack 11 in which piezoelectric elements 12 are arranged alternately with internal electrode layers 13a and 13b in stacks. The stack-like actuator body 11 is sintered to form a monolithic block from the piezoceramic layers 12 with electrode layers 13a or 13b applied thereto and porous intermediate layers 17, which are arranged therebetween, for forming the predetermined breaking points. The internal electrode layers 13a and 13b alternately lead to two outer faces of the actuator stack, where they are electrically conductively connected to a metallization 14a or 14b.

An expandable electrode structure 15 is attached to the outer face of the surface metallization 14a or 14b by a contact element 16, wherein the region of the predetermined breaking points 17 of the piezo stack is cutout. The contact element 16 is, for example, conductive adhesive or solder. A fixed connection between the electrode structure 15 and the metallization 14 is formed outside the regions of the predetermined breaking points 17 by said contact element. A separate electrode structure 15 is attached to each of the metallizations 14a and 14b.

The electrode structure 15 comprises a wire mesh which is designed to be expandable at least in the region of the predetermined breaking points. An external electrical voltage can be applied to the piezoelectric component at the electrode structures 15 by means of connection elements. The voltage is applied to the individual piezoceramic layers 12 via the internal electrodes 13a and 13b. As a result, the individual piezoceramic layers experience a change in thickness, as a result of which the length of the stack-like actuator body changes. On account of the predetermined breaking points 17 in the actuator body, the change in length at the side faces of the actuator stack 11 takes place substantially in the region of the predetermined breaking points 17. In contrast, the relative change in length at the outer faces in the regions between the predetermined breaking points 17 is comparatively low. Therefore, a fixed connection between the electrode wire mesh 15 and the metallization 14a or 14b can be maintained. The contact element 16 is interrupted only in the region of the predetermined breaking points 17, and therefore the expandable wire mesh 15 can elastically compensate the movement of the piezo stack in this region.

FIG. 2 shows a second example embodiment of the piezoelectric component, which may be embodied for example as a piezoelectric actuator of a fuel injection valve in a motor vehicle, with identical components being provided with the same reference symbols as shown in the embodiment of FIG. 1. The layered body 11 comprising piezoceramic layers 12 and internal electrodes 13a and 13b and also the predetermined breaking points 17 is of identical design to the layered body of the first exemplary embodiment from FIG. 1. However, in contrast to the first exemplary embodiment, the metallization 14a and 14b is interrupted in the region of the predetermined breaking points 17 in this case. The metallization 14a and 14b usually has an adhesion promoter which firstly ensures adhesion of the surface metallization on the ceramic stack 11 and secondly makes it possible for solder or conductive adhesive to adhere to the metallization layer. The cutout in the surface metallization 14a and 14b in the region of the predetermined breaking point 17 has the result that solder or conductive adhesive which is applied over the surface or continuously in said region does not adhere to the ceramic layer element. There is therefore a cutout between the electrode 15 and the layered body in the region of the predetermined breaking points 17.

An expandable electrode structure 15, for example a wire mesh or a meandering metallic structure, can maintain its ability to expand even when solder or conductive adhesive is applied to it.

The ability to expand is restricted only when the contact-making arrangement is fixedly connected to the surface metallization of a ceramic body 11 by the solder or the conductive adhesive. In this way, the ability of the electrode 15 to expand in the region of the predetermined breaking points 17 can be utilized, and the interruption in the surface metallization 14a or 14b can therefore be bridged, in the case of the design variant illustrated in FIG. 2 too.

The disclosed piezoelectric component therefore has a reliable contact-making arrangement for piezoelectric layer elements with a lower stiffness than conventional contact-making arrangements. Since the ability of the contact-making arrangement or the wire mesh electrode or meandering structure to expand can be limited to regions of the predetermined breaking points, substantially more simple and more cost-effective electrode structures are possible in this case.

What is claimed is:

1. A piezoelectric component, comprising:
a stack-like actuator body comprising a plurality of piezoelectric elements and internal electrode layers arranged in an alternating manner in a stacking direction,
wherein each internal electrode layers is conductively connected to one of two metallizations on an outer face of the stack in an alternating manner,
wherein each metallization is connected to an electrically conductive electrode structure by an electrically conductive contact element, and
wherein the stack-like actuator body has at least one predetermined breaking point, and at least one of the metallizations and the contact elements have a cutout in the region of the at least one predetermined breaking point.

2. The piezoelectric component of claim 1, wherein each contact element, except in the region of the at least one predetermined breaking point, forms a fixed connection between a respective metallization and corresponding electrode structure.

3. The piezoelectric component of claim 1, wherein contact element comprises solder or conductive adhesive.

4. The piezoelectric component of claim 1, wherein each electrode structure is expandable at least in the region of the at least one predetermined breaking point.

5. The piezoelectric component of claim 1, wherein each electrode structure comprises a metallic mesh or has a meandering metallic structure.

6. The piezoelectric component of claim 1, wherein the stack-like actuator body forms a monolithic structure.

7. A fuel injection valve for use in a motor vehicle, the fuel injection comprising:
a piezoelectric actuator including:
a stack-like actuator body comprising a plurality of piezoelectric elements and internal electrode layers arranged in an alternating manner in a stacking direction,
wherein each internal electrode layers is conductively connected to one of two metallizations on an outer face of the stack in an alternating manner,
wherein each metallization is connected to an electrically conductive electrode structure by an electrically conductive contact element,
wherein the stack-like actuator body has at least one predetermined breaking point, and at least one of the metallizations and the contact elements have a cutout in the region of the at least one predetermined breaking point.

8. The fuel injection valve of claim 7, wherein each contact element, except in the region of the at least one predetermined breaking point, forms a fixed connection between a respective metallization and corresponding electrode structure.

9. The fuel injection valve of claim 7, wherein each contact element comprises solder or conductive adhesive.

10. The fuel injection valve of claim 7, wherein each electrode structure is expandable at least in the region of the at least one predetermined breaking point.

11. The fuel injection valve of claim 7, wherein each electrode structure comprises a metallic mesh or has a meandering metallic structure.

12. The fuel injection valve of claim 7, wherein the stack-like actuator body forms a monolithic structure.
